(19) United States
(12) Patent Application Publication
(10) Pub. No.: US 2010/0073096 A1
(43) Pub. Date: Mar. 25, 2010

(54) MICRO ELECTRO-MECHANICAL SYSTEM BASED PROGRAMMABLE FREQUENCY SYNTHESIZER AND METHOD OF OPERATION THEREOF

(75) Inventor: Arun K. Gupta, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/235,484

(22) Filed: Sep. 22, 2008

(51) Int. Cl. H03L 7/00

(52) U.S. Cl. 331/35

(57) ABSTRACT

A frequency synthesizer and a method of synthesizing an output signal. In one embodiment, the frequency synthesizer includes: (1) a substrate, (2) a resonator located on the substrate and comprising a micro electromechanical system device and a feedback amplifier coupled thereto, (3) a phase-locked loop located on the substrate and coupled to the resonator, (4) control logic located on the substrate and configured to control the phase-locked loop based on a known resonant frequency of the micro electromechanical system device and (5) a voltage-controlled oscillator located on the substrate and coupled to the phase-locked loop.

### TECHNICAL FIELD OF THE INVENTION

The invention is directed, in general, to frequency synthesizers and, more specifically, to a micro electro-mechanical system (MEMS) based programmable frequency synthesizer and a method of operating the same to synthesize a signal of programmable frequency.

### BACKGROUND OF THE INVENTION

Frequency synthesizers are used to drive, synchronize the operation of, and provide references to, a wide variety of electronic circuits. To name just a few, frequency synthesizers are used to generate clock signals in networks, computers and video displays and enable modulation and demodulation in wireless communication devices. As operating frequencies of these circuits have increased over the years, the demands on the output signals their frequency synthesizers provide have concomitantly increased. Today's frequency synthesizers should not only be capable of generating a high (e.g., megahertz or gigahertz-range) frequency output signal, they should do so with a minimum of phase noise, frequency jitter or drift or temperature-or age-dependent amplitude or frequency degradation.

Many circuits are required to operate over a wide frequency band or over multiple frequency bands. Multiple frequency synthesizers having different output frequencies may certainly be employed to meet this requirement, but it is far more practical and efficient to employ a single programmable frequency synthesizer instead. An analog or digital value is provided to the programmable frequency synthesizer, and the programmable frequency synthesizer responds by producing an output signal having a frequency that corresponds to the value.

Integrating circuits into ever-fewer substrates (sometimes called chips or dies) has also been an objective for circuit designers for many years. Most conventional frequency synthesizers employ a vibrating crystal to produce an oscillating reference signal for the output signals they generate. Frequency synthesizers need a crystal (typically quartz) reference oscillator to keep phase noise low. Unfortunately, crystals require trimming to produce accurate reference oscillations. Trimming is time-consuming and expensive. Crystals also cannot be monolithically formed onto an integrated circuit (IC) substrate. Thus, most conventional clocks exist as separate chips, which frustrates integration efforts and prevents small, particularly mobile, devices from shrinking further in size.

### SUMMARY OF THE INVENTION

To address the above-discussed deficiencies of the prior art, the invention provides a frequency synthesizer. In one embodiment, the frequency synthesizer includes: (1) a substrate, (2) a resonator located on the substrate and comprising a MEMS device and a feedback amplifier coupled thereto, (3) a phase-locked loop (PLL) located on the substrate and coupled to the resonator, (4) control logic located on the substrate and configured to control the PLL based on a known resonant frequency of the MEMS device and (5) a voltage-controlled oscillator (VCO) located on the substrate and coupled to the PLL.

In another embodiment, the frequency synthesizer is a programmable frequency synthesizer. The programmable frequency synthesizer includes: (1) a substrate, (2) a resonator located on the substrate and comprising an untrimmed MEMS device and a feedback amplifier coupled thereto, (3) a fractional-N PLL located on the substrate and coupled to the resonator, (4) a memory located on the substrate and configured to contain a value representing a known resonant frequency of the MEMS device, (5) a temperature sensor located on the substrate proximate the MEMS device, (6) control logic located on the substrate and configured to control the fractional-N PLL based on the known resonant frequency, a desired output frequency value and a temperature proximate the MEMS device and (7) a VCO located on the substrate and coupled to the fractional-N PLL.

Another aspect of the invention provides a method of synthesizing an output signal. In one embodiment, the method includes: (1) causing a MEMS device and a feedback amplifier coupled thereto to resonate with one another to generate a reference oscillation, (2) providing the reference oscillation to a PLL, (3) controlling the PLL based on a known resonant frequency of the MEMS device and (4) exciting a VCO with an output of the PLL.

### BRIEF DESCRIPTION OF THE DRAWINGS

For a more complete understanding of the invention, reference is now made to the following descriptions taken in conjunction with the accompanying drawings, in which:

FIG. 1 is a highly simplified block diagram of an IC in which a programmable frequency synthesizer constructed according to the principles of the invention may be employed;

FIG. 2 is a block diagram of one embodiment of a programmable frequency synthesizer constructed according to the principles of the invention;

FIG. 3 is a block diagram of one embodiment of the VCO of FIG. 2; and

FIG. 4 is a flow diagram of one embodiment of a method of synthesizing an output signal of programmable frequency carried out according to the principles of the invention.

### DETAILED DESCRIPTION

Described herein are various embodiments of a frequency synthesizer that can be formed monolithically, i.e., integrated on or in (“on” and “in” being regarded as synonymous for purposes of the invention) a single substrate. Certain of the embodiments exhibit significantly reduced phase noise, frequency jitter and drift and temperature- and age-dependent amplitude or frequency degradation. Certain of the embodiments are suitable for providing frequency references in the megahertz-to-gigahertz range. Some of the embodiments provide an output signal of fixed, unprogrammable frequency. Other of the embodiments have a programmable output frequency.

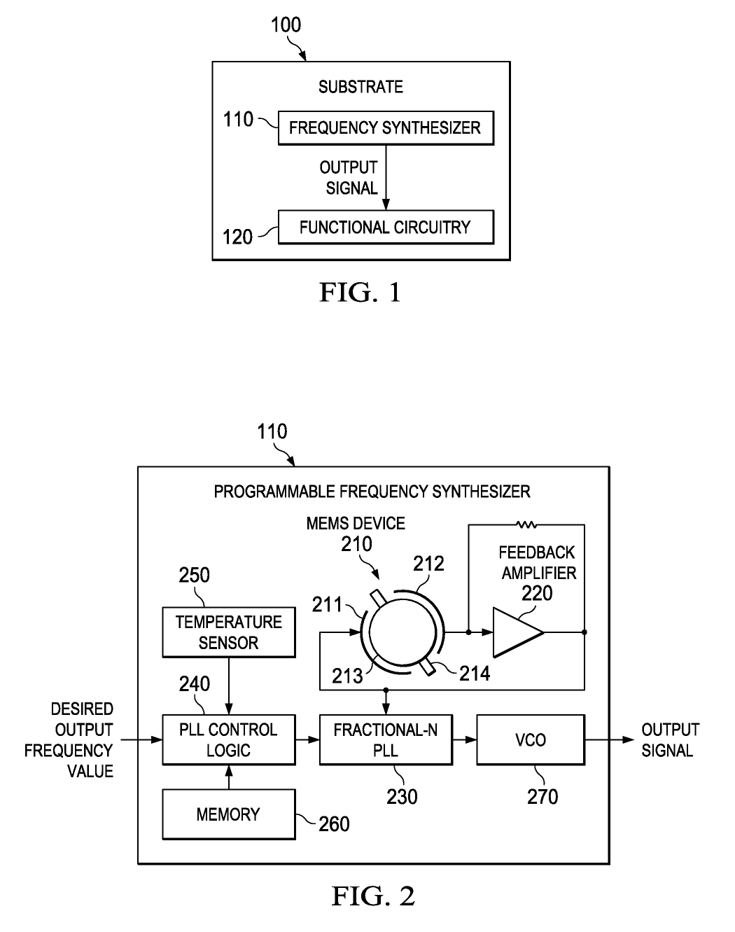

FIG. 1 is a highly simplified block diagram of an IC in which a frequency synthesizer 110 constructed according to the principles of the invention may be employed. The frequency synthesizer 110 is located on an IC substrate 100 that also contains functional circuitry 120 to which the frequency synthesizer 110 provides an output signal. The functional circuitry 120 may, for example, include digital logic for which the output signal functions as a clock signal. The functional circuitry 120 may, as a further example, include mixing circuitry that employs the output signal to modulate or demodulate a radio-frequency (RF) signal as part of conducting wireless, for example cellular telephone or Personal Communication Service (PCS) communication. From FIG. 1, it is apparent that the frequency synthesizer 110 is integratable with the functional circuitry 120 to form a single IC on a common substrate.

FIG. 2 is a block diagram of one embodiment of the programmable frequency synthesizer of FIG. 1. The programmable frequency synthesizer 110 includes a resonator. However, the resonator is not crystal-based. Instead, the resonator includes a MEMS device 210 and a feedback amplifier 220 coupled to the MEMS device 210. An output 211 of the MEMS device 210 is coupled to an input of the feedback amplifier 220, and an output of the feedback amplifier 220 is coupled to an input 212 of the MEMS device 210 such that an electric current circulates and resonates through the MEMS device 210 and the feedback amplifier 220. Consequently, a reference signal is generated having a frequency that is based on the resonant frequency of the MEMS device 210. In the illustrated embodiment, the frequency of the reference signal is substantially the same as the resonant frequency of the MEMS device 210. The physical characteristics of the MEMS device 210, including its temperature, determine its resonant frequency. For this reason, its resonant frequency can be determined ahead of time, or known.

In the illustrated embodiment, the MEMS device 210 includes a body 213 that constitutes a resonating mass in which vibrational energy is isolated from the underlying substrate in some manner. In one embodiment, the body 213 is isolated from the substrate by being suspended above the substrate with relatively thin, narrow anchors 214. The body 213 is driven into resonance through an input actuator 211. In one embodiment, the input actuator 211 is an electrostatic actuator. In another embodiment, the input actuator 211 is a piezoelectric actuator. In yet another embodiment, the input actuator 211 is of another conventional or later-developed type. The input 211 An output 212 produces an output signal based on the vibrational energy contained in the body 213. In one embodiment, the output 212 is electrostatic. In another embodiment, the output 212 is piezoelectric. In yet another embodiment, the output 212 is of another conventional or later-developed type. In one embodiment, the MEMS device 210 is constructed according to the teachings of U.S. Pat. No. 6,965,177, which issued on Nov. 15, 2005, to Turner, et al., entitled “Pulse Drive of Resonant MEMS Devices,” commonly assigned with this invention and incorporated herein by reference. However, the invention encompasses other conventional or later-developed types of MEMS devices that can resonate.

In the embodiment of FIG. 2, the MEMS device 210 is untrimmed. Those skilled in the pertinent art are familiar with the practice of trimming mechanical structures such as crystals and MEMS devices to alter their resonant frequency(ies). For example, various trimming techniques are described in Hsu, et al., “Frequency Trimming for MEMS Resonator Oscillators,” Frequency Control Symposium, 2007 Joint with the 21^{st} European Frequency and Time Forum, pp. 1088-1091, 2007. Those skilled in the art likewise understand that trimming is frequently carried out in gross and fine steps and can be tedious, time consuming and therefore expensive. The embodiment of FIG. 2 advantageously eliminates the need to trim the MEMS device 210, so its resonant frequency may vary from device to device. Compensation for variations in its resonant frequency is carried out in subsequent circuitry, namely a PLL to be described below. In an alternative embodiment, the MEMS device 210 is grossly trimmed to within a particular range of resonant frequencies. In another alternative embodiment, the MEMS device 210 is also finely trimmed to a particular resonant frequency.

The feedback amplifier 220 may be of any topology or type. In the embodiment of FIG. 2, the feedback amplifier 220 is illustrated as being a simple operational amplifier having a feedback resistor (unreferenced). In the illustrated embodiment, the feedback amplifier 220 receives the output signal from the output 212 and produces and provides drive pulses to the input 211 of the MEMS device 210. U.S. Pat. No. 6,965,177, supra, teaches how current pulses may be employed to drive a resonant MEMS device. In one embodiment, the feedback amplifier 220 operates, and the MEMS device 220 responds, according to the teachings of U.S. Pat. No. 6,965,177. However, other embodiments fall within the scope of the invention. As stated above, the resonator produces a reference signal. In the embodiment of FIG. 2, the reference signal is taken from the output of the feedback amplifier 220. In an alternative embodiment, the reference signal is taken from the output of the MEMS device 210.

The programmable frequency synthesizer 110 further includes a PLL 230 coupled to the resonator. In the embodiment of FIG. 2, the PLL 230 is a fractional-N PLL. That is, the PLL 230 is configured to divide the reference signal by a noninteger number N to provide an output signal. In this embodiment, the PLL 230 compensates for any variability in the resonant frequency of the MEMS device 210, allowing the MEMS device 210 to be untrimmed. The PLL 230 may be constructed according to the teachings of U.S. Pat. No. 6,593,783, which issued on Jul. 15, 2003, to Ichimaru, entitled “Compensation Circuit for Fractional-N Frequency PLL Synthesizer,” commonly assigned with this invention and incorporated herein by reference. In an alternative embodiment, the PLL 230 is an integer N PLL, wherein the PLL is configured to divide the reference signal by an integer N.

The programmable frequency synthesizer 110 further includes PLL control logic 240 coupled to the PLL 230. The PLL control logic 240 is configured to control the PLL 230 based on the known resonant frequency of the MEMS device 210. More specifically, the PLL control logic 240 is configured to process various information, calculate a dynamic value for N, and feed the dynamic value to the PLL 230. In the embodiment of FIG. 2, the PLL control logic 240 is configured to receive a value representing a desired output frequency and control the PLL 230 based on that desired output frequency value. This is the mechanism that makes the programmable frequency synthesizer 110 of FIG. 2 programmable. In an alternative embodiment, the PLL control logic 240 is not configured to receive a desired output frequency value, and thus the frequency synthesizer is not programmable.

The programmable frequency synthesizer 110 further includes a temperature sensor 250. The temperature sensor 250 is located proximate the MEMS device 210 and provides a signal to the PLL control logic 240 that indicates a temperature proximate the MEMS device 210. In the embodiment of FIG. 2, the PLL control logic 240 is configured to control the PLL 230 also based on the temperature proximate the MEMS device 210. Temperature compensation at least reduces the degree to which the output signal of the programmable frequency synthesizer 110 is temperature-dependent. In the embodiment of FIG. 2, that temperature-dependence is substantially reduced.

In an alternative embodiment, the programmable frequency synthesizer 110 includes one or more controllable heaters proximate the MEMS device 210. The controllable heaters, if included, allow the temperature of the MEMS resonator 210 to be controlled to within a desired range or to a desired temperature. In a more specific embodiment, the MEMS device 210 may be constructed according to the teachings of U.S. Pat. No. 7,282,393, which issued on Oct. 16, 2007, to Tarn, entitled “Micro Electro-Mechanical Device Packages with Integral Heaters,” commonly assigned with this invention and incorporated herein by reference.

The programmable frequency synthesizer 110 further includes a memory 260. In the embodiment of FIG. 2, the memory 260 is a programmable read-only memory (PROM) configured to contain a value representing the known resonant frequency. The memory 260 may contain multiple of such values, e.g., each representing a value for a single temperature or a relatively small range of temperatures, the values together representing a temperature-dependent curve of resonant frequencies.

The programmable frequency synthesizer 110 further includes a VCO 270. The VCO 270 is coupled to the PLL 230 to receive the output signal thereof. The PLL 230 is configured to lock the VCO 270 with the output of the resonator. In response, the VCO 270 produces the output signal that may be provided to functional circuitry (e.g., the functional circuitry 120 of FIG. 1). In one embodiment, the PLL 230 tunes the VCO 270 according to the teachings of U.S. Pat. No. 6,545,547, which issued on Apr. 8, 2003, to Fridi, et al., entitled “Method for Tuning a VCO Using a Phase Lock Loop,” commonly assigned with this invention and incorporated herein by reference. In various alternative embodiments, the VCO 270 employs complementary metal-oxide semiconductor (CMOS) devices, diodes or another type of device to provide variable capacitance. However, the VCO 270 of FIG. 2 includes varactors constructed from MEMS devices.

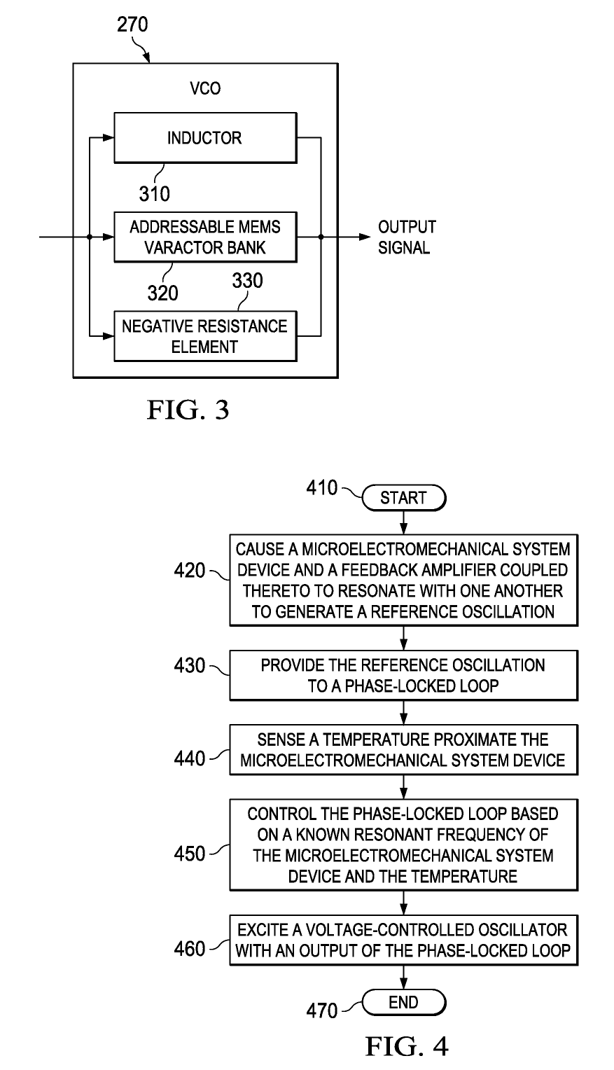

FIG. 3 is a block diagram of one embodiment of the VCO 270 of FIG. 2. The embodiment of FIG. 3 includes an inductor 310, a MEMS varactor bank 320 including at least one MEMS varactor and a negative resistance element 330. The frequency of the VCO 270 is controlled by tuning a varactor in the MEMS varactor bank 320 to produce a high-quality (low variability) output signal employable as a frequency reference. The VCO 270 is a positive feedback amplifier having a tuned resonator in its feedback loop. Oscillations occur at the resonant frequency, which is typically changed, or tuned, by varying the resonator capacitance. The VCO 270 is tuned by applying a control voltage across a varactor in the MEMS varactor bank 320. In cellular and PCS wireless communication bands, most VCOs are “negative resistance” types, with a resonator in their transistor base or emitter.

In the embodiment of FIG. 3, the MEMS varactor bank 320 includes high-Q MEMS RF varactors. In one embodiment, the MEMS varactor bank 320 is constructed according to the teachings of U.S. Pat. No. 6,635,919, which issued on Oct. 21, 2003, to Melendez, et al., entitled “High Q-Large Tuning Range Micro-Electro Mechanical System (MEMS) Varactor for Broadband Applications,” commonly assigned with this invention d incorporated herein by reference. However, the MEMS varactor bank may be constructed in any manner whatsoever without departing from the scope of the invention.

FIG. 4 is a flow diagram of one embodiment of a method of synthesizing an output signal of programmable frequency carried out according to the principles of the invention. The method begins in a start step 410. In a step 420, a MEMS device and a feedback amplifier coupled thereto are caused to resonate with one another to generate a reference oscillation. In a step 430, the reference oscillation that results from the resonance is provided to a PLL. In a step 440 pertaining to a specific embodiment, a temperature proximate the MEMS device is sensed. In a step 450, the PLL is controlled based on a known resonant frequency of the MEMS device and, in the specific embodiment, the temperature. In a step 460, a VCO is excited with an output of the PLL. The method ends in an end step 470.

Those skilled in the art to which the invention relates will appreciate that other and further additions, deletions, substitutions and modifications may be made to the described embodiments without departing from the scope of the invention.

What is claimed is:

1. A frequency synthesizer, comprising:
a substrate;
a resonator located on said substrate and comprising a micro electromechanical system device and a feedback amplifier coupled thereto;
a phase-locked loop located on said substrate and coupled to said resonator;
control logic located on said substrate and configured to control said phase-locked loop based on a known resonant frequency of said micro electro-mechanical system device; and
a voltage-controlled oscillator located on said substrate and coupled to said phase-locked loop.

2. The frequency synthesizer as recited in claim 1 wherein said frequency synthesizer is a programmable frequency synthesizer, said control logic configured to control said phase-locked loop based on said known resonant frequency of said micro electromechanical system device and a desired output frequency value.

3. The frequency synthesizer as recited in claim 1 wherein said phase-locked loop is a fractional-N phase-locked loop.

4. The frequency synthesizer as recited in claim 1 further comprising a temperature sensor located on said substrate proximate said micro electromechanical system device, said control logic configured to control said phase-locked loop based on said known resonant frequency of said micro electro-mechanical system device and a temperature proximate said micro electro-mechanical system device.

5. The frequency synthesizer as recited in claim 1 wherein said micro electromechanical system device comprises a body suspended by anchors.

6. The frequency synthesizer as recited in claim 1 further comprising a memory located on said substrate and configured to contain a value representing said known resonant frequency, said micro electromechanical system device being untrimmed.

7. The frequency synthesizer as recited in claim 1 further comprising functional circuitry located on said substrate and configured to be driven by an output signal produced by said voltage-controlled oscillator.

8. The frequency synthesizer as recited in claim 1 wherein said voltage controlled oscillator comprises further micro electro-mechanical system varactors.

9. A method of synthesizing an output signal, comprising:
causing a micro electromechanical system device and a feedback amplifier coupled thereto to resonate with one another to generate a reference oscillation;
providing said reference oscillation to a phase-locked loop;
controlling said phase-locked loop based on a known resonant frequency of said micro electromechanical system device; and
exciting a voltage-controlled oscillator with an output of said phase-locked loop.

10. The method as recited in claim 9 wherein said controlling comprises controlling said phase-locked loop based on said known resonant frequency of said micro electro-mechanical system device and a desired output frequency value.

11. The method as recited in claim 9 further comprising dividing said reference oscillation by a fractional N.

12. The method as recited in claim 9 further comprising sensing a temperature proximate said micro electromechanical system device, said controlling comprising controlling said phase-locked loop based on said known resonant frequency of said micro electromechanical system device and said temperature, said micro electro-mechanical system device being untrimmed.

13. The method as recited in claim 9 wherein said causing comprises vibrating a body of said micro electro-mechanical system.

14. The method as recited in claim 9 further comprising:
determining a value representing said known resonant frequency; and
storing said value in a memory.

15. The method as recited in claim 9 further comprising driving functional circuitry with a clock signal produced by said voltage-controlled oscillator.

16. The method as recited in claim 9 further comprising generating variable capacitances in said voltage controlled oscillator with at least one further micro electromechanical system varactor.

17. A programmable frequency synthesizer, comprising:
a substrate;
a resonator located on said substrate and comprising an untrimmed micro electro-mechanical system device and a feedback amplifier coupled thereto;
a fractional-N phase-locked loop located on said substrate and coupled to said resonator;
a memory located on said substrate and configured to contain a value representing a known resonant frequency of said micro electromechanical system device;
a temperature sensor located on said substrate proximate said micro electro-mechanical system device;
control logic located on said substrate and configured to control said fractional-N phase-locked loop based on said known resonant frequency, a desired output frequency value and a temperature proximate said micro electromechanical system device; and
a voltage-controlled oscillator located on said substrate and coupled to said fractional-N phase-locked loop.

18. The programmable frequency synthesizer as recited in claim 17 wherein said micro electromechanical system device comprises a body suspended by anchors.

19. The programmable frequency synthesizer as recited in claim 17 further comprising functional circuitry located on said substrate and configured to be driven by an output signal produced by said voltage-controlled oscillator.

20. The programmable frequency synthesizer as recited in claim 17 wherein said voltage controlled oscillator comprises further micro electro-mechanical system varactors.
